(19) United States
(12) Patent Application Publication
(10) Pub. No.: US 2022/0190202 A1
(43) Pub. Date: Jun. 16, 2022

(54) LIGHT-EMITTING ELEMENT AND METHOD FOR MANUFACTURING THE SAME

(71) Applicant: TOYODA GOSEI CO., LTD., Kiyosu-shi (JP)

(72) Inventors: Kengo NAGATA, Kiyosu-shi (JP); Yoshiki SAITO, Kiyosu-shi (JP); Keita KATAOKA, Nagakute-shi (JP); Tetsuo NARITA, Nagakute-shi (JP); Kayo KONDO, Nagakute-shi (JP)

(21) Appl. No.: 17/529,777

(22) Filed: Nov. 18, 2021

(30) Foreign Application Priority Data
Dec. 16, 2020 (JP) 2020-208841

(51) Int. Cl. H01L 33/32; H01L 33/00

(52) U.S. Cl. CPC H01L 33/32; H01L 33/0075

(57) ABSTRACT

A light-emitting element includes an n-type contact layer which includes AlGaN and in which a Fermi level and a conduction band are in degeneracy, and a light-emitting layer including AlGaN and being stacked on the n-type contact layer. An Al composition x of the n-type contact layer is not less than 0.1 greater than an Al composition x of the light-emitting layer. The n-type contact layer has an effective donor concentration that is a concentration to cause the degeneracy and that is not more than 4.0×10¹⁹ cm⁻³.

### CROSS-REFERENCE TO RELATED APPLICATIONS

The present patent application claims the priority of Japanese patent application No. 2020/208841 filed on Dec. 16, 2020, and the entire contents of Japanese patent application No. 2020/208841 are hereby incorporated by reference.

### TECHNICAL FIELD

The present invention relates to a light-emitting element and a method for manufacturing the light-emitting element.

### BACKGROUND ART

A technique is known which uses a degenerately doped gallium nitride layer as a tunnel junction in a light-emitting diode (LED) (see, e.g., Patent Literature 1). “Degenerately doped” mentioned above is considered to mean that the Fermi level and the conduction band are overlapped (or degenerated) due to doping a dopant at a high concentration. Semiconductors in which the Fermi level and the conduction band are degenerated usually behave similarly to a metal and have reduced electrical resistance. In addition, since such semiconductors behave similarly to a metal, there is no temperature dependency in electrical resistance. Therefore, LEDs using a degenerately doped gallium nitride layer as the tunnel junction can be expected to be driven in a wide temperature range.

### CITATION LIST

### Patent Literature

Patent Literature 1: JP patent No. 5,726,405

### SUMMARY OF INVENTION

Concerning n-type AlGaN including a group IV element such as Si as a dopant, according as a concentration of the group IV element is increased, electric resistance decreases in the same manner as that of general semiconductors up to a certain concentration, but starts to increase conversely once exceeding the certain concentration. For this reason, even by the known usual method where the concentration of the group IV element is simply increased, it is not possible to effectively reduce the electric resistance.

It is an object of the invention to provide a light-emitting element which includes an n-type contact layer including an AlGaN with a group IV element dopant such that the electrical resistance can be effectively reduced by the degeneracy of the Fermi level and the conduction band, as well as a method for manufacturing the light-emitting element.

According to an aspect of the invention, a light-emitting element as set forth in (1) to (5) below and a method for manufacturing a light-emitting element as set forth in (6) and (7) below are provided.

(1) A light-emitting element, comprising:
an n-type contact layer which comprises AlGaN and in which a Fermi level and a conduction band are in degeneracy; and
a light-emitting layer comprising AlGaN and being stacked on the n-type contact layer,
wherein an Al composition x of the n-type contact layer is not less than 0.1 greater than an Al composition x of the light-emitting layer, and
wherein the n-type contact layer has an effective donor concentration that is a concentration to cause the degeneracy and that is not more than 4.0×10¹⁹ cm⁻³.
   (2) The light-emitting element as defined in (1) above, wherein the effective donor concentration in the n-type contact layer is (−3.0×10¹⁸) x³+(9.3×10¹⁸) x²+(8.1×10¹⁸) x+1.6×10¹⁸ cm⁻³ (where x is the Al composition x of the n-type contact layer).
   (3) The light-emitting element as defined in (1) or (2) above, wherein the Al composition x of the n-type contact layer is not less than 0.5.
   (4) The light-emitting element as defined in any one of (1) to (3) above, wherein the Al composition x of the n-type contact layer is not more than 0.7.
   (5) The light-emitting element as defined in any one of (1) to (4) above, wherein electrical resistivity of the n-type contact layer is not more than 5×10⁻² Ω·cm.
   (6) A method for manufacturing a light-emitting element, comprising:
by a vapor-phase growth method, forming an n-type contact layer which comprises AlGaN and in which a Fermi level and a conduction band are in degeneracy; and
forming a light-emitting layer comprising AlGaN on the n-type contact layer,
wherein an Al composition x of the n-type contact layer is not less than 0.1 greater than an Al composition x of the light-emitting layer,
wherein the n-type contact layer has an effective donor concentration that is a concentration to cause the degeneracy and that is not more than 4.0×10¹⁹ cm⁻³, and
wherein a V/III ratio of a source gas of the n-type contact layer in the forming the n-type contact layer is within a range of not less than 1000 and not more than 3200.
   (7) The method as defined in (6) above, wherein a growth temperature of the n-type contact layer in the forming of the n-type contact layer is not more than 1150° C.

### Effects of Invention

According to an aspect of the invention, a light-emitting element can be provided which includes an n-type contact layer including an AlGaN with a group IV element dopant such that the electrical resistance can be effectively reduced by the degeneracy of the Fermi level and the conduction band, as well as a method for manufacturing the light-emitting element.

### BRIEF DESCRIPTION OF DRAWINGS

FIG. 1 is a vertical cross-sectional view showing a light-emitting element in an embodiment of the present invention.

FIG. 2 is a graph showing plotted points of lower limits of an effective donor concentration at which degeneracy occurs in AlGaN with Al compositions of 0%, 50%, 62% and 100%, and also showing an approximate curve of the points.

FIG. 3 is a graph showing a relationship between an Al composition and electrical resistivity for an n-type contact layer.

FIGS. 4A to 4C are graphs showing a relationship between a Si concentration and electrical resistivity for the n-type contact layer.

FIGS. 5A to 5C are graphs showing temperature dependency in electrical resistivity, carrier concentration and mobility for the n-type contact layer.

FIG. 6 is a graph showing a relationship between a V/III ratio of a source gas and electrical resistivity for the n-type contact layer.

FIG. 7 is a graph showing a relationship between a growth temperature and electrical resistivity for the n-type contact layer.

FIGS. 8A to 8C are diagrams illustrating spectra obtained by cathodoluminescence measurement on various n-type contact layers.

FIG. 9 is a graph showing a relationship between an effective donor concentration N_{d}−Nₐ and a concentration of Si as a group IV element for each sample.

FIG. 10 is a graph showing temperature dependency in electrical resistivity ρ of samples #1, #2, #8 and #9 in Groups A and C.

FIG. 11 is a graph showing a relationship between an energy E₁ and the effective donor concentration N_{d}−Nₐ for the samples #1, #2, #8 and #9 in the groups A and C.

FIG. 12A is a graph showing plotted points of values of E_{d,0} for AlGaN with an Al composition x of 0 and AlGaN with an Al composition x of 0.62, and also showing a straight line passing through these two points.

FIG. 12B is a graph showing plotted points of values of a for the AlGaN with the Al composition x of 0 and the AlGaN with the Al composition x of 0.62, and also showing a straight line passing through these two points.

### DESCRIPTION OF EMBODIMENTS

### (Configuration of a Light-Emitting Element)

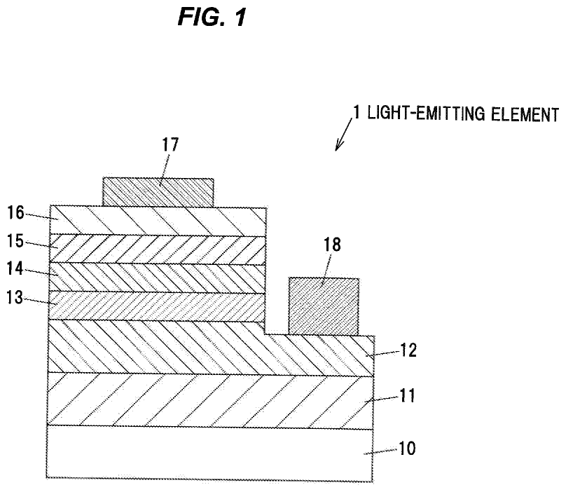

FIG. 1 is a vertical cross-sectional view showing a light-emitting element 1 in an embodiment of the invention. The light-emitting element 1 is a flip chip-type light-emitting diode (LED) and includes a substrate 10, a buffer layer 11 on the substrate 10, an n-type contact layer 12 on the buffer layer 11, a light-emitting layer 13 on the n-type contact layer 12, an electron blocking layer 14 on the light-emitting layer 13, a p-type contact layer 15 on the electron blocking layer 14, a transparent electrode 16 on the p-type contact layer 15, a p-electrode 17 connected to the transparent electrode 16, and an n-electrode 18 connected to the n-type contact layer 12.

“On (preposition indicating position)” in the configuration of the light-emitting element 1 is “on” when the light-emitting element 1 is placed in a direction as shown in FIG. 1, and it means a direction from the substrate 10 toward the p-electrode 17.

The substrate 10 is a growth substrate formed of sapphire. A thickness of the substrate 10 is, e.g., 900 μm. In addition to sapphire, it is possible to use AlN, Si, SiC, ZnO, etc., as a material of the substrate 10.

The buffer layer 11 has a structure in which, e.g., three layers; a nucleation layer, a low-temperature buffer layer and a high-temperature buffer layer, are sequentially stacked. The nucleation layer is a layer that is formed of non-doped AlN grown at a low temperature and is a nucleus of crystal growth. A thickness of the nucleation layer is, e.g., 10 nm. The low-temperature buffer layer is a layer that is formed of non-doped AlN grown at a higher temperature than the nucleation layer. A thickness of the low-temperature buffer layer is, e.g., 0.3 μm. The high-temperature buffer layer is a layer that is formed of non-doped AlN grown at a higher temperature than the low-temperature buffer layer. A thickness of the high-temperature buffer layer is, e.g., 2.7 μm. A threading dislocation density in AlN is reduced by providing such a buffer layer 11.

The light-emitting layer 13 is a layer stacked on the n-type contact layer 12. The light-emitting layer 13 is formed of AlGaN and preferably has a multiple quantum well (MQW) structure. An Al composition x of the light-emitting layer 13 (an Al composition x of well layers when having the MQW structure) is set according to a desired emission wavelength and is set to, e.g., 0.35 to 0.45 when the emission wavelength is about 280 nm. The Al composition x here is a proportion of an Al content when the total of a Ga content and the Al content is defined as 1, and is expressed as AlₓGa₁₋ₓN (0≤x≤1) in an ideal composition of AlGaN.

The light-emitting layer 13 has, e.g., a MQW structure having two well layers, i.e., a structure in which a first barrier layer, a first well layer, a second barrier layer, a second well layer and a third barrier layer are stacked in this order. The first well layer and the second well layer are formed of n-type AlGaN. The first barrier layer, the second barrier layer and the third barrier layer are formed of n-type AlGaN with a higher Al composition (including the Al composition x of 1, i.e., AlN) than the first well layer and the second well layer.

As an example, an Al composition x, a thickness and a concentration of Si as a dopant for each of the first well layer and the second well layer are 0.4, 2.4 nm and 9×10¹⁸/cm³. An Al composition x, a thickness and a concentration of Si as a dopant for each of the first barrier layer and the second barrier layer are 0.55, 19 nm and 9×10¹⁸/cm³. An Al composition x, a thickness and a concentration of Si as a dopant for the third barrier layer are 0.55, 4 nm and 5×10¹⁸/cm³.

The n-type contact layer 12 is formed of n-type AlGaN including a group IV element, such as Si or Ge, as a donor. The lower limit of the Al composition x of the n-type contact layer 12 is set as a lower limit of a range in which absorption of light emitted from the light-emitting layer 13 can be suppressed. Absorption of light emitted from the light-emitting layer 13 by the n-type contact layer 12 can be effectively suppressed when the Al composition x of the n-type contact layer 12 is not less than 0.1 greater than the Al composition x of AlGaN constituting the light-emitting layer 13 (the Al composition x of the well layers when the light-emitting layer 13 has the MQW structure), and the absorption can be suppressed more effectively when the Al composition x of the n-type contact layer 12 is not less than 0.15 greater than the Al composition x of AlGaN constituting the light-emitting layer 13. Thus, the Al composition x of the n-type contact layer 12 is preferably not less than 0.1, more preferably not less than 0.15, greater than the Al composition x of the light-emitting layer 13.

In case that the Al composition x of the light-emitting layer 13 is, e.g., 0.35 to 0.45, light with a wavelength of about 280 nm is emitted, the absorption can be effectively suppressed when the Al composition x of the n-type contact layer 12 is not less than 0.5, and the absorption can be suppressed more effectively when the Al composition x of the n-type contact layer 12 is not less than 0.55.

Meanwhile, the upper limit of the Al composition x of the n-type contact layer 12 can be set as an upper limit of a range in which an increase in electrical resistance with an increase in the Al composition x can be suppressed. When the Al composition x is increased, electrical resistance of AlGaN is substantially constant up to the Al composition x of 0.7 and starts to increase when exceeding 0.7. For this reason, the Al composition x of the n-type contact layer 12 is preferably set to not more than 0.7.

Thus, as a preferable example when the light-emitting element 1 is an ultraviolet light-emitting element, the Al composition x of the n-type contact layer 12 is within the range of not less than 0.5 and not more than 0.7. In this case, the n-type contact layer 12 ideally has a composition expressed by AlₓGa₁₋ₓN (0.5≤x≤0.7).

The n-type contact layer 12 also has an effective donor concentration N_{d}−Nₐ at which a Fermi level and a conduction band are degenerated. Here, N_{d} is a donor concentration and Nₐ is an acceptor concentration. When N_{d}−Nₐ is not more than 4.0×10¹⁹ cm³, self-compensation due to complex defects of group III vacancies and group IV elements hardly occurs and a value of N_{d}−Nₐ is thus substantially equal to a value obtained by subtracting a concentration of an element acting as an acceptor from a concentration of a group IV element acting as a donor in the n-type contact layer 12. An impurity concentration can be measured by secondary ion mass spectrometry (SIMS).

In AlGaN, group IV elements serve as a donor when entered the Ga or Al site, and serve as an acceptor when entered the N site. In AlGaN, C has a property of easily entering the N site and the group IV elements other than C have a property of easily entering the Ga or Al site. Therefore, usually, the group IV element serving as an acceptor in AlGaN is mainly C. In addition, not only C intentionally added as a dopant but also, e.g., C included in a group III raw material used in MOCVD, etc., are incorporated into AlGaN. Therefore, regardless of the type of group IV element used as a donor, the acceptor concentration Nₐ is usually substantially equal to a concentration of C, and if incorporation of C into the n-type contact layer 12 can be suppressed by adjusting the growth temperature, etc., the effective donor concentration N_{d}−Nₐ becomes substantially equal to a concentration of the group IV element.

According to Non-Patent Literature “A. Wolos et al., “Properties of metal-insulator transition and electron spin relaxation in GaN:Si”, PHYSICAL REVIEW B 83, 165206 (2011)”, the Fermi level and the conduction band are degenerated in GaN including Si as a dopant when the Si concentration is not less than 1.6×10¹⁸ cm⁻³. In this regard, it is considered that this Si concentration condition can be generalized as the effective donor concentration N_{d}−Nₐ condition, including the case where GaN includes an acceptor. That is, the lower limit of the Si concentration at which degeneracy occurs in AlGaN with the Al composition x of 0 (GaN) is 1.6×10¹⁸ cm³.

The present inventors also derived that the lower limit of the effective donor concentration N_{d}−Nₐ at which degeneracy occurs in AlGaN with the Al composition x of 0.62 (Al_{0.62}Ga_{0.38}N) is 9.5×10¹⁸ cm⁻³. A method for this derivation will be described later.

Furthermore, the present inventors derived that the lower limit of the effective donor concentration N_{d}−Nₐ at which degeneracy occurs in AlGaN with the Al composition of 0.5 (Al_{0.5}Ga_{0.5}N) is 7.6×10¹⁸ cm⁻³, and the lower limit of the effective donor concentration N_{d}-Nₐ at which degeneracy occurs in AlGaN with the Al composition of 1 (AlN) is 1.6×10¹⁹ cm⁻³. A method for this derivation will be described later.

In AlGaN including a group IV element as a donor, the Fermi level and the conduction band usually can be made degenerate by increasing the effective donor concentration N_{d}−Nₐ. However, when the effective donor concentration N_{d}−Nₐ exceeds 4.0×10¹⁹ cm⁻³, the complex defects of group III vacancies and group IV elements are formed, self-compensation occurs and electrical resistance is thus not effectively reduced.

The details of the complex defects of group III vacancies and group IV elements have not yet been revealed, but one possible likelihood is that when the group IV element does not enter the group III vacancy generated in the process of growing AlGaN and stays at another location, the group IV element cannot behave as a donor (cannot emit electrons) and one to three holes are emitted depending on the state.

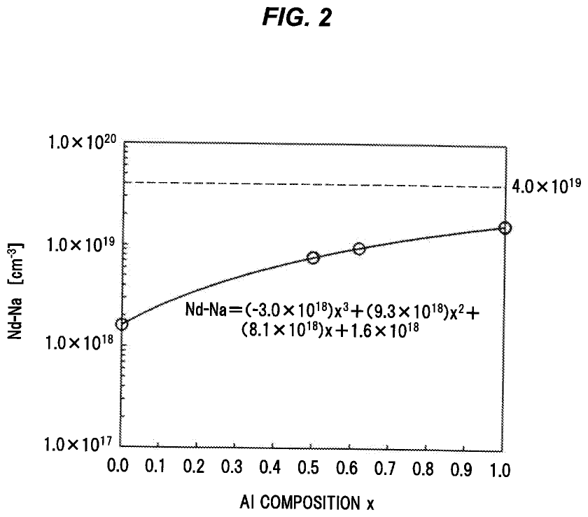

FIG. 2 is a graph showing plotted points of lower limits of the effective donor concentration at which degeneracy occurs in the above-described AlGaN with the Al compositions x of 0, 0.5, 0.62 and 1 (GaN, Al_{0.5}Ga_{0.5}N, Al_{0.62}Ga_{0.38}N, AlN), and also showing an approximate curve of the points. The approximate curve in FIG. 2 is expressed by the formula N_{d}−Nₐ=(−3.0×10¹⁸) x³+(9.3×10¹⁸) x²+(8.1×10¹⁸) x+1.6×10¹⁸ as a function of the Al composition x.

The Fermi level and the conduction band of the n-type contact layer 12 become degenerate when the effective donor concentration N_{d}−Nₐ is above the approximate curve in FIG. 2, i.e., not less than (−3.0×10¹⁸) x³+(9.3×10¹⁸) x²+(8.1×10¹⁸) x+1.6×10¹⁸, and not more than 4.0×10¹⁹ cm⁻³.

In the present embodiment, the n-type contact layer 12 can have electrical resistivity of not more than 5×10⁻² Ω·cm by respectively setting, e.g., the concentration of the group IV element in the n-type contact layer 12 within a range of not less than 5×10¹⁸ cm⁻³ and not more than 4×10¹⁹ cm⁻³, the growth temperature of the n-type contact layer 12 within a range of not less than 850° C. and not more than 1100° C., and the V/III ratio of the source gas of the n-type contact layer 12 (described later) within a range of not less than 1000 and not more than 3200. In addition, it is considered that the lower limit of electrical resistivity of the n-type contact layer 12 under these conditions of the concentration of the group IV element, the growth temperature and the V/III ratio of the source gas of the n-type contact layer 12 is about 1×10⁻³ Ω·cm. The thickness of the n-type contact layer 12 is, e.g., 500 to 3000 nm.

The electron blocking layer 14 is formed of p-type AlGaN with a higher Al composition x than the third barrier layer. Diffusion of electrons to the p-type contact layer 15 side is suppressed by the electron blocking layer 14. An Al composition x, a thickness and a concentration of Mg as a dopant for the electron blocking layer 14 are, e.g., respectively 0.8, 25 nm and 5×10¹⁹/cm³.

The p-type contact layer 15 has a structure in which a first p-type contact layer and a second p-type contact layer are sequentially stacked. The first p-type contact layer and the second p-type contact layer are formed of p-type GaN. A thickness and a concentration of Mg as a dopant for the first p-type contact layer are, e.g., respectively 700 nm and 2×10¹⁹/cm³. Meanwhile, a thickness and a concentration of Mg as a dopant for the second p-type contact layer are, e.g., respectively 60 nm and 1×10²⁰/cm³.

A trench is provided in a part of a region on a surface of the p-type contact layer 15. The trench penetrates the p-type contact layer 15 and the light-emitting layer 13 and reaches the n-type contact layer 12, and the n-electrode 18 is connected to a surface of the n-type contact layer 12 exposed by the trench.

The transparent electrode 16 is formed of, e.g., a conductive oxide transparent to visible light, such as IZO, ITO, ICO, ZnO. When light emitted from the light-emitting layer 13 is ultraviolet light (light of not more than 365 nm), a large amount of the light is absorbed by the p-type contact layer 15 formed of GaN and does not pass through the p-electrode 17, hence, reflected light from the p-electrode 17 is not obtained. In this regard, however, when the thin p-type contact layer 15 formed of GaN or the p-type contact layer 15 formed of AlGaN is used and the thin transparent electrode 16 or the transparent electrode 16 formed of a material transparent to ultraviolet light is used, absorption of the ultraviolet light thereby can be suppressed and light output can thus be significantly increased. The p-electrode 17 is formed of, e.g., Ni/Au. The n-electrode 18 is formed of, e.g., Ti/Al/Ni, V/Al/Ni, or V/Al/Ru, etc.

The light-emitting element 1 may be of a face-up type. In addition, the characteristic configuration of the light-emitting element 1 such as the n-type contact layer 12 can be applied to light-emitting elements other than LED, such as laser diode.

### (Method for Manufacturing the Light-Emitting Element)

Next, an example of a method for manufacturing the light-emitting element 1 in the embodiment of the invention will be described. When forming each layer of the light-emitting element 1 by a vapor-phase growth method, a Ga source gas, an Al source gas and an N source gas used are, e.g., respectively trimethylgallium, trimethylaluminum and ammonia. Meanwhile, an n-type dopant source gas and a p-type dopant source gas used are, e.g., respectively a silane gas, which is a Si source gas, and a bis (cyclopentadienyl) magnesium gas, which is a Mg source gas. In addition, a carrier gas used is, e.g., a hydrogen gas or a nitrogen gas. The growth temperature of each layer in the present embodiment is temperature of a heater of a film formation apparatus and a surface temperature of the substrate 10 is about 100° C. lower than the temperature of the heater.

Firstly, the substrate 10 is prepared and the buffer layer 11 is formed thereon. When forming the buffer layer 11, the nucleation layer formed of AlN is firstly formed by sputtering. The growth temperature is, e.g., 880° C. Next, the low-temperature buffer layer and the high-temperature buffer layer, which are formed of AlN, are sequentially formed on the nucleation layer by the MOCVD method. The growth conditions for the low-temperature buffer layer are, e.g., a growth temperature of 1090° C. and a growth pressure of 50 mbar. The growth conditions for the high-temperature buffer layer are, e.g., a growth temperature of 1270° C. and a growth pressure of 50 mbar.

Next, the n-type contact layer 12 formed of AlGaN including a group IV element such as Si is formed on the buffer layer 11 by the MOCVD method. When forming the n-type contact layer 12, the V/III ratio of the source gas of the n-type contact layer 12 is set within a range of not less than 1000 and not more than 3200 to reduce electrical resistance of the n-type contact layer 12. The V/III ratio here means a ratio of the number of group III element atoms (Ag, Al) and the number of group V element atoms (N) in the source gas.

In addition, when forming the n-type contact layer 12, the growth temperature of the n-type contact layer 12 is preferably set to not more than 1150° C. An increase in electrical resistance with an increase in the growth temperature can be suppressed by setting the growth temperature to not more than 1150° C. It is considered that this is because evaporation of the group III elements, particularly Ga which easily evaporates, is suppressed, the excessive generation of group III vacancies is thus suppressed, and an increase in electrical resistance due to the influence of the complex defects of group III vacancies and group IV elements is thereby suppressed.

When forming the n-type contact layer 12, the growth temperature of the n-type contact layer 12 is also preferably set to not less than 850° C. When the growth temperature is less than 850° C., ammonia, which is a source of the group V element N, is less likely to be decomposed, hence, a supply amount of ammonia needs to be increased and the V/III ratio needs to be set abnormally high. In addition, when the growth temperature is low, there may arise a problem that C from the group III source material is incorporated. Therefore, the growth temperature is preferably set to a temperature at which this problem can be avoided, e.g., not less than 850° C.

Meanwhile, the growth pressure of the n-type contact layer 12 is set to, e.g., 20 to 200 mbar.

Next, the light-emitting layer 13 is formed on the n-type contact layer 12 by the MOCVD method. The light-emitting layer 13 is formed by stacking the first barrier layer, the first well layer, the second barrier layer, the second well layer and the third barrier layer in this order. The growth conditions for the light-emitting layer 13 are, e.g., a growth temperature of 975° C. and a growth pressure of 400 mbar.

Next, the electron blocking layer 14 is formed on the light-emitting layer 13 by the MOCVD method. The growth conditions for the electron blocking layer 14 are, e.g., a growth temperature of 1025° C. and a growth pressure of 50 mbar.

Next, the p-type contact layer 15 is formed on the electron blocking layer 14 by the MOCVD method. The p-type contact layer 15 is formed by stacking the first p-type contact layer and the second p-type contact layer in this order. The growth conditions for the first p-type contact layer are, e.g., a growth temperature of 1,050° C. and a growth pressure of 200 mbar. The growth conditions for the second p-type contact layer are, e.g., a growth temperature of 1050° C. and a growth pressure of 100 mbar.

Next, a predetermined region on the surface of the p-type contact layer 15 is dry etched and a trench with a depth reaching the n-type contact layer 12 is thereby formed.

Next, the transparent electrode 16 is formed on the p-type contact layer 15. Next, the p-electrode 17 is formed on the transparent electrode 16 and the n-electrode 18 is formed on the n-type contact layer 12 exposed on the bottom surface of the trench. The transparent electrode 16, the p-electrode 17 and the n-electrode 18 are formed by sputtering or vapor deposition, etc.

### Effects of the Embodiment

In the embodiment of the invention, it is possible to obtain the n-type contact layer that is formed of AlGaN and has electrical resistance effectively reduced by suppressing the amount of the complex defects of group III vacancies and group IV elements and causing degeneracy of the Fermi level and the conduction band. Output of the light-emitting element relative to the forward current can be increased by reducing electrical resistance of the n-type contact layer. In addition, since the electrical resistance of the n-type contact layer in which the Fermi level and the conduction band are degenerated does not have temperature dependency, the light-emitting element can be driven in a wide temperature range.

### Example 1

Next, evaluation results of characteristics of the n-type contact layer 12 in the embodiment of the invention will be described. In Example 1, the n-type contact layers 12 were formed on the substrates 10 via the buffer layers 11 under various conditions (described later), and these n-type contact layers 12 were evaluated. The configurations and the growth conditions for the substrate 10, the buffer layer 11 and the n-type contact layer 12 in Example 1 are shown n Table 1 below. Si was used as an n-type dopant in the n-type contact layer 12.

TABLE 1

| | | | | Growth | Growth |
|---|---|---|---|---|---|
| | | | Thickness | temperature | pressure |
| | | Material | [μm] | [° C.] | [mbar] |
| n-type contact layer 12 | | AlGaN | 1.3 | 980 | 50 |
| Buffer layer 11 | High- | AlN | 2.7 | 1270 | 50 |
| | temperature | | | | |
| | buffer layer | | | | |
| | Low-temperature | AlN | 0.3 | 1090 | 50 |
| | buffer layer | | | | |
| | Nucleation layer | AlN | 0.01 | 880 | — |

| | | | | |
|---|---|---|---|---|
| Substrate 10 | Sapphire | 1.7 | — | — |

In Example 1, the electrical resistivity, the carrier concentration and the mobility for the n-type contact layer 12 were measured by Hall effect measurement and the Si concentration was measured by secondary ion mass spectrometry (SIMS).

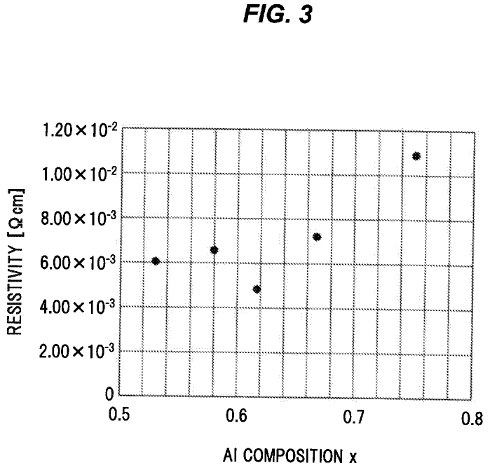

FIG. 3 is a graph showing a relationship between the Al composition x and electrical resistivity for the n-type contact layer 12. FIG. 3 shows that electrical resistance increases when the Al composition x of the n-type contact layer 12 exceeds about 0.7. Numerical values of the points plotted in FIG. 3 and the growth temperature and the V/III ratio of the source gas of the n-type contact layer 12 for each plotted point are shown in Table 2 below.

TABLE 2

| Growth temperature | | | Resistivity |
|---|---|---|---|
| [° C.] | V/III ratio | Al composition x | [Ωcm] |
| 1013 | 1586 | 0.580 | 6.56 × 10⁻³ |
| 1024 | 1591 | 0.530 | 6.04 × 10⁻³ |
| 1024 | 1588 | 0.617 | 4.83 × 10⁻³ |
| 1024 | 1588 | 0.668 | 7.21 × 10⁻³ |
| 1024 | 1587 | 0.752 | 1.09 × 10⁻² |

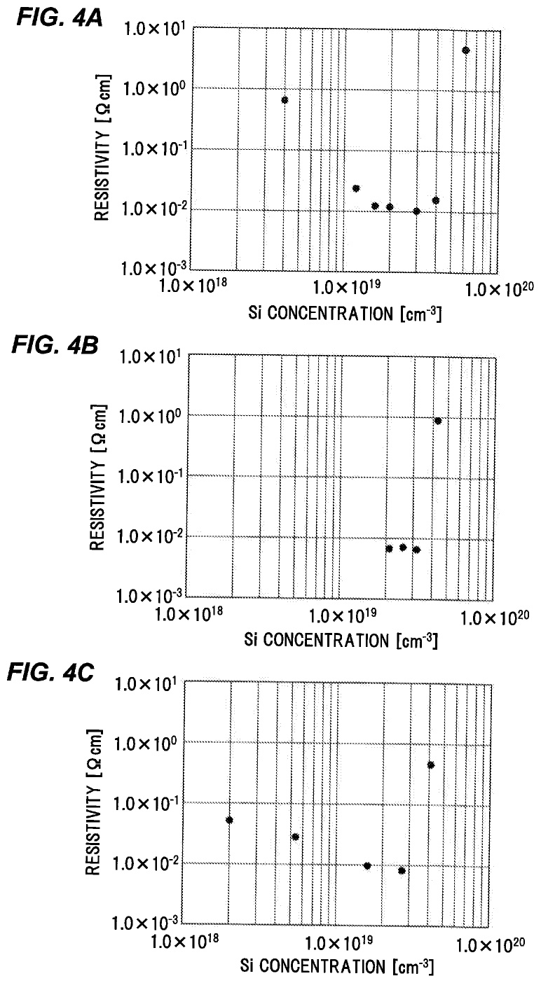

FIGS. 4A to 4C are graphs showing a relationship between the Si concentration and electrical resistivity for the n-type contact layer 12. The growth temperature and the V/III ratio of the source gas of the n-type contact layer 12 relevant to FIG. 4A are respectively 1013° C. and 1058. The growth temperature and the V/III ratio of the source gas of the n-type contact layer 12 relevant to FIG. 4B are respectively 1013° C. and 1587. The growth temperature and the V/III ratio of the source gas of the n-type contact layer 12 relevant to FIG. 4C are respectively 1083° C. and 1058. FIGS. 4A to 4C show that electrical resistance increases when the Si concentration in the n-type contact layer 12 exceeds about 4.0×10¹⁹ cm⁻³. Numerical values of the points plotted in FIG. 4 are shown in Table 3 below.

TABLE 3

| Growth temperature | | Si concentration | Resistivity |
|---|---|---|---|
| [° C.] | V/III ratio | [cm⁻³] | [Ωcm] |
| 1013 | 1058 | 2.0 × 10¹⁹ | 1.2 × 10⁻² |
| | | 4.0 × 10¹⁸ | 6.5 × 10⁻¹ |
| | | 1.2 × 10¹⁹ | 2.4 × 10⁻² |
| | | 1.6 × 10¹⁹ | 1.2 × 10⁻² |
| | | 3.0 × 10¹⁹ | 1.0 × 10⁻² |
| | | 4.0 × 10¹⁹ | 1.5 × 10⁻² |
| | | 6.0 × 10¹⁹ | 4.8 |
| 1013 | 1587 | 3.2 × 10¹⁹ | 6.6 × 10⁻³ |
| | | 4.3 × 10¹⁹ | 8.8 × 10⁻¹ |
| | | 2.1 × 10¹⁹ | 6.8 × 10⁻³ |
| | | 2.6 × 10¹⁹ | 7.1 × 10⁻³ |
| 1083 | 1058 | 2.0 × 10¹⁸ | 5.2 × 10⁻² |
| | | 5.4 × 10¹⁸ | 2.8 × 10⁻² |
| | | 1.6 × 10¹⁹ | 9.6 × 10⁻³ |
| | | 4.1 × 10¹⁹ | 4.6 × 10⁻¹ |
| | | 2.7 × 10¹⁹ | 8.2 × 10⁻³ |

According to FIGS. 4A to 4C and Table 3, to reduce electrical resistivity of the n-type contact layer 12 to, e.g., not more than 5×10⁻² Ω·cm, the Si concentration should be set to 1.2×10¹⁹ to 4.0×10¹⁹ cm⁻³ when the growth temperature and the V/III ratio of the source gas of the n-type contact layer 12 are respectively 1013° C. and 1508, the Si concentration should be set to 2.1×10¹⁹ to 3.2×10¹⁹ cm⁻³ when the growth temperature and the V/III ratio of the source gas of the n-type contact layer 12 are respectively 1013° C. and 1587, and the Si concentration should be set to 5.4×10¹⁸ to 2.7×10¹⁹ cm⁻³ when the growth temperature and the V/III ratio of the source gas of the n-type contact layer 12 are respectively 1083° C. and 1058.

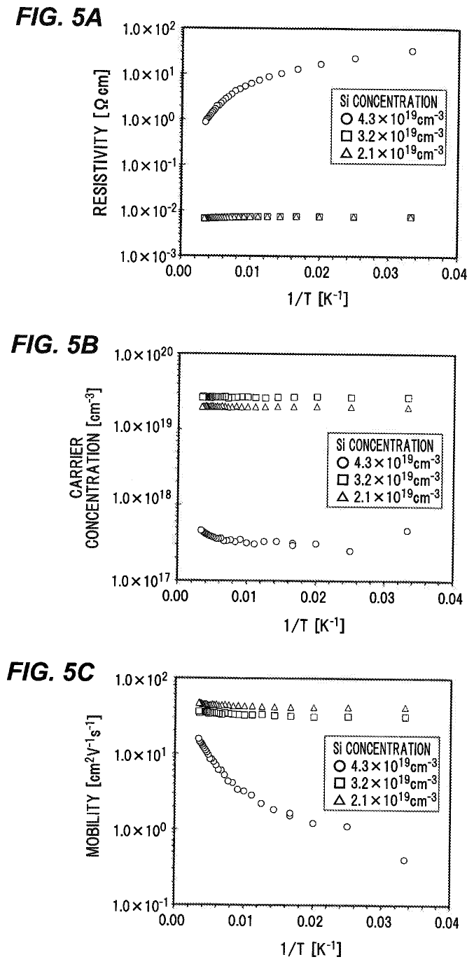

FIGS. 5A to 5C are graphs showing temperature dependency in electrical resistivity, carrier concentration and mobility for the n-type contact layer 12. FIGS. 5A to 5C show the measured values of the three n-type contact layers 12 respectively having the Si concentrations of 2.10×10¹⁹ cm³, 3.20×10¹⁹ cm⁻³ and 4.30×10¹⁹ cm⁻³. The growth temperature and the V/III ratio of the source gas of the n-type contact layer 12 having the Si concentration of 2.10×10¹⁹ cm⁻³ are respectively 1013° C. and 1587, the growth temperature and the V/III ratio of the source gas of the n-type contact layer 12 having the Si concentration of 3.20×10¹⁹ cm⁻³ are respectively 1013° C. and 1587, and the growth temperature and the V/III ratio of the source gas of the n-type contact layer 12 having the Si concentration of 4.30×10¹⁹ cm⁻³ are respectively 1043° C. and 1587.

In n-type AlGaN in which the Fermi level and the conduction band are degenerated, there is almost no temperature dependency in the carrier concentration. According to FIG. 5B, the n-type contact layers 12 having the Si concentrations of 2.10×10¹⁹ cm⁻³ and 3.20×10¹⁹ cm⁻³ have small temperature dependency in the carrier concentration and it can thus be determined that the Fermi level and the conduction band are degenerated.

On the other hand, the n-type contact layer 12 having the Si concentration of 4.30×10¹⁹ cm⁻³ has temperature dependency in the carrier concentration and it can thus be determined that the Fermi level and the conduction band are not degenerate. It is considered that the reason why degeneracy is not observed in the n-type contact layer 12 having the Si concentration of 4.30×10¹⁹ cm⁻³ even though the Si concentration is high enough is that the Fermi level is reduced due to compensation of electrons and the degeneracy is lifted.

According to FIG. 5C, there is almost no temperature dependency in mobility in the n-type contact layers 12 having the Si concentrations of 2.10×10¹⁹ cm⁻³ and 3.20×10¹⁹ cm⁻³, but there is relatively large temperature dependency in mobility in the n-type contact layer 12 having the Si concentration of 4.30×10¹⁹ cm⁻³. It is considered that this is because many complex defects of group III vacancies and Si are present in the n-type contact layer 12 having the Si concentration of 4.30×10¹⁹ cm⁻³ due to the Si high concentration and the carriers are scattered by these complex defects.

In addition, according to FIG. 5A, there is almost no temperature dependency in electrical resistivity in the n-type contact layers 12 having the Si concentrations of 2.10×10¹⁹ cm⁻³ and 3.20×10¹⁹ cm⁻³, but there is relatively large temperature dependency in electrical resistivity in the n-type contact layer 12 having the Si concentration of 4.30×10¹⁹ cm⁻³. It is considered that this is because many complex defects of group III vacancies and Si are present in the n-type contact layer 12 having the Si concentration of 4.30×10¹⁹ cm⁻³.

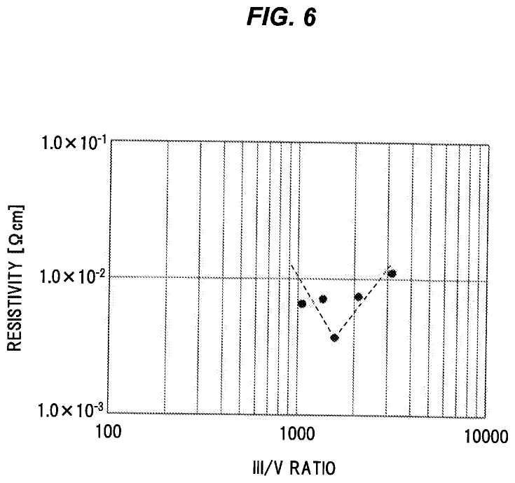

FIG. 6 is a graph showing a relationship between the V/III ratio of the source gas and electrical resistivity for the n-type contact layer 12. The growth temperature of the n-type contact layer 12 relevant to FIG. 6 is 1013° C. FIG. 6 shows that electrical resistivity takes the smallest value when the V/III ratio of the source gas of the n-type contact layer 12 is about 1500 and low resistivity is obtained when the V/III ratio of the source gas is within the range of not less than 1000 and not more than 3200. Numerical values of the points plotted in FIG. 6 are shown in Table 4 below.

TABLE 4

| V/III ratio | Resistivity [Ωcm] |
|---|---|
| 1058 | 6.53 × 10⁻³ |
| 1366 | 7.10 × 10⁻³ |
| 1586 | 3.71 × 10⁻³ |
| 2115 | 7.45 × 10⁻³ |
| 3172 | 1.11 × 10⁻² |

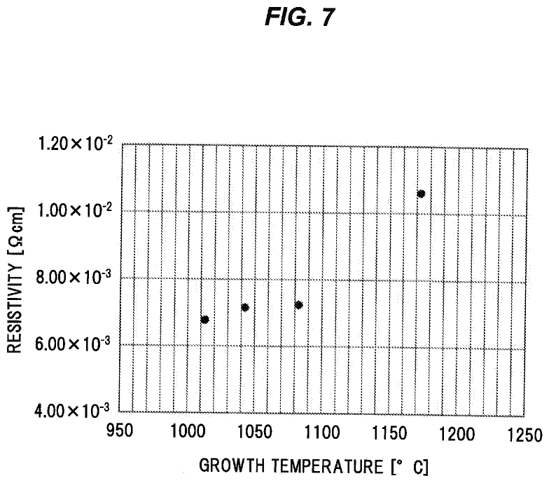

FIG. 7 is a graph showing a relationship between the growth temperature and electrical resistivity for the n-type contact layer 12. FIG. 7 shows that electrical resistance starts to increase when the growth temperature of the n-type contact layer 12 is between 1100 and 1150° C. Numerical values of the points plotted in FIG. 7 and the V/III ratio of the source gas of the n-type contact layer 12 for each plotted point are shown in Table 5 below.

TABLE 5

| Growth temperature | | Resistivity |
|---|---|---|
| [° C.] | V/III ratio | [Ωcm] |
| 1013 | 3174 | 6.77 × 10⁻³ |
| 1043 | 1058 | 7.15 × 10⁻³ |
| 1083 | 1586 | 7.24 × 10⁻³ |
| 1173 | 1058 | 1.06 × 10⁻² |

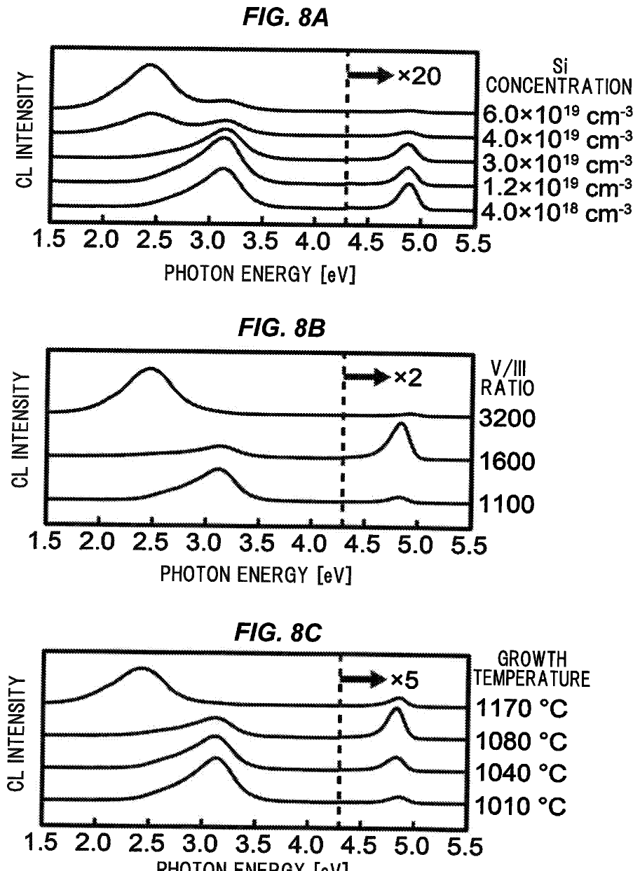

FIGS. 8A to 8C show spectra (CL spectra) obtained by cathodoluminescence measurement on various n-type contact layers 12. A peak of the CL spectrum of the n-type contact layer 12 at a photon energy of around 2.4 eV is due to light emission caused by the complex defects of group III vacancies and Si, and the larger the intensity of this peak, the more the number of the complex defects of group III vacancies and Si.

Meanwhile, a peak at a photon energy of around 3.2 eV is due to light emission caused by C on the group V site, and a peak at a photon energy of around 4.9 eV is due to light emission corresponding to the band gap.

FIG. 8A shows a change in the shape of the CL spectrum of the n-type contact layer 12 due to the Si concentration. According to FIG. 8A, the peak caused by the complex defects of group III vacancies and Si is not observed for the n-type contact layers 12 having the Si concentrations of 4.0×10¹⁸ to 3.0×10¹⁹ cm⁻³, appears slightly for the n-type contact layer 12 having the Si concentration of 4.0×10¹⁹ cm⁻³, and appears strongly for the n-type contact layer 12 having the Si concentration of 6.0×10¹⁹ cm⁻³.

Since the electrical resistance of the n-type contact layer 12 increases with an increase in the number of the complex defects of group III vacancies and Si, the result obtained from FIG. 8A is consistent with the result obtained from FIGS. 4A to 4C which shows that electrical resistance increases when the Si concentration in the n-type contact layer 12 exceeds about 4.0×10¹⁹ cm⁻³.

FIG. 8B shows a change in the shape of the CL spectrum of the n-type contact layer 12 due to the V/III ratio of the source gas. According to FIG. 8B, the peak caused by the complex defects of group III vacancies and Si is not observed for the n-type contact layers 12 formed using source gases with the V/III ratio of 1100 to 1600, and is observed for the n-type contact layer 12 formed using a source gas with the V/III ratio of 3200.

Since the electrical resistance of the n-type contact layer 12 increases with an increase in the number of the complex defects of group III vacancies and Si, the result obtained from FIG. 8B is consistent with the result obtained from FIG. 6 which shows that low resistivity is obtained when the V/III ratio of the source gas of the n-type contact layer 12 is within the range of not less than 1000 and not more than 3200.

FIG. 8C shows a change in the shape of the CL spectrum of the n-type contact layer 12 due to the growth temperature. According to FIG. 8C, the peak caused by the complex defects of group III vacancies and Si is not observed for the n-type contact layers 12 formed at the growth temperatures of 1010 to 1080° C., and is observed for the n-type contact layer 12 formed at the growth temperature of 1170° C.

Since the electrical resistance of the n-type contact layer 12 increases with an increase in the number of the complex defects of group III vacancies and Si, the result obtained from FIG. 8C is consistent with the result obtained from FIG. 7 which shows that electrical resistance starts to increase when the growth temperature of the n-type contact layer 12 is between 1100 and 1150° C.

Although Si was used as the n-type dopant in the n-type contact layer 12 for each evaluation in Example 1, similar evaluation results are obtained also when using a group IV element other than Si, such as Ge.

### Example 2

Described next is the derivation method to derive that the lower limit of the effective donor concentration N_{d}−Nₐ at which degeneracy occurs in AlGaN with the Al composition x of 0.62 (Al_{0.62}Ga_{0.38}N) is 9.5×10¹⁸ cm⁻³, which is mentioned above in the embodiment of the invention.

In Example 2, plural Al_{0.62}Ga_{0.38}N having different Si concentrations (samples #1 to #9) were made, and Si and C concentrations, electrical resistivity, electron concentration and effective donor concentration N_{d}−Nₐ were measured for each sample.

Here, the Si and C concentrations in each sample were measured by SIMS. The electrical resistivity and the electron concentration were estimated from the results of van-der-Pauw method and Hall effect measurement in the temperature range of 30 to 300K. The effective donor concentration N_{d}−Nₐ was estimated from the result of electrochemical capacitance-voltage (C-V) measurement using a 0.1 mol/l NaOH solution as an electrolyte. Static relative permittivity of Al_{0.62}Ga_{0.38}N was presumed to be 8.66 by linear interpolation between 8.9, which is relative permittivity of GaN, and 8.5, which is relative permittivity of AlN.

Measurement results of the samples #1 to #9 are shown in Table 6 below. n₃₀₀K and ρ₃₀₀K in Table 6 are respectively the electron concentration and the electrical resistivity at 300K. n_{300K} and ρ_{300K} of the samples #1, #2 and #4 were directly measured by a Hall device, and n_{300K} and ρ_{300K} of the samples #3, #5, #7, #8 and #9 were estimated from calibration samples produced under the same growth conditions.

In Table 6, the samples #1 and #2 doped with a low concentration of Si are classified into Group A, the samples #3 to #7 doped with a medium concentration of Si are classified into Group B, and the samples #8 and #9 doped with a high concentration of Si are classified into Group C.

TABLE 6

| | | Si | C | | | |
|---|---|---|---|---|---|---|
| | | concentration | concentration | n_{300 K} | N_{d}-Nₐ | ρ_{300 K} |
| Sample | | (cm⁻³) | (cm⁻³) | (cm⁻³) | (cm⁻³) | (Ω cm) |
| Group | #1 | 3.7 × 10¹⁸ | 7.4 × 10¹⁷ | 1.7 × 10¹⁸ | 2.3 × 10¹⁸ | 5.3 × 10⁻² |
| A | #2 | 6.5 × 10¹⁸ | 5.9 × 10¹⁸ | 9.8 × 10¹⁷ | 9.3 × 10¹⁷ | 6.0 × 10⁻¹ |
| Group | #3 | 9.2 × 10¹⁸ | 1.8 × 10¹⁸ | 7.8 × 10¹⁸ | 8.9 × 10¹⁸ | 1.8 × 10⁻² |
| B | #4 | 2.0 × 10¹⁹ | 4.4 × 10¹⁸ | 1.8 × 10¹⁹ | 1.4 × 10¹⁹ | 1.2 × 10⁻² |
| | #5 | 2.1 × 10¹⁹ | 1.8 × 10¹⁸ | 2.0 × 10¹⁹ | 1.8 × 10¹⁹ | 6.7 × 10⁻³ |
| | #6 | 3.2 × 10¹⁹ | 1.8 × 10¹⁸ | 2.6 × 10¹⁹ | 2.1 × 10¹⁹ | 6.6 × 10⁻³ |
| | #7 | 4.0 × 10¹⁹ | 4.4 × 10¹⁸ | 1.8 × 10¹⁹ | 1.1 × 10¹⁹ | 1.2 × 10⁻² |
| Group | #8 | 4.3 × 10¹⁹ | 1.8 × 10¹⁸ | 4.6 × 10¹⁷ | 3.5 × 10¹⁷ | 8.6 × 10⁻¹ |
| C | #9 | 6.0 × 10¹⁹ | 4.4 × 10¹⁸ | 3.0 × 10¹⁷ | 2.6 × 10¹⁷ | 4.9 |

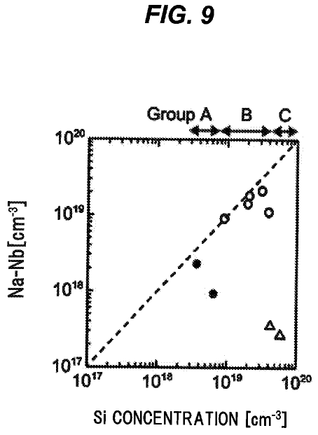

FIG. 9 is a graph showing a relationship between the effective donor concentration N_{d}−Nₐ and the concentration of Si as a group IV element for each sample. According to FIG. 9, the effective donor concentration is substantially equal to the Si concentration in Groups A and B, except the sample #2. This shows that almost all Si is activated and there is substantially no electronic compensation.

The sample #2 had a low effective donor concentration relative to the Si concentration and a high electrical resistance. It is considered that this is because the concentration of C, which acts as an acceptor and compensates free electrons, on the N site is high. In the sample #2, the C concentration was 5.9×10¹⁸ cm⁻³ and was comparable to the Si concentration of 6.5×10¹⁸ cm⁻³, as shown in Table 6. In addition, the effective donor concentration N_{d}−Nₐ in the sample #2 was 9.3×10¹⁷ cm⁻³ and was close to 6.0×10¹⁷ cm⁻³ which is a value obtained by subtracting the C concentration from the Si concentration. This shows that most of electrons in the sample #2 were trapped by C on the N site, resulting in an increase in electrical resistance.

In contrast to this, the effective donor concentration (N_{d}−Nₐ) in the samples #8 and #9 in Group C, which were doped with a high concentration of Si, was two orders of magnitude lower than the Si concentration. This is because electrons in the samples #8 and #9 were significantly compensated by the complex defects of group III vacancies and group IV elements.

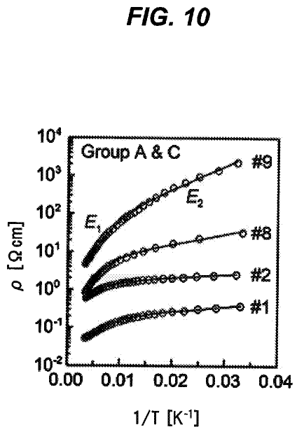

FIG. 10 is a graph showing temperature dependency in electrical resistivity p of the samples #1, #2, #8 and #9 in Groups A and C. In the samples doped with Si at a concentration slightly lower than a concentration causing degeneracy, such as the samples in Group A, there is a possibility that an impurity band is formed.

A multiplicative inverse of electrical resistivity ρ (i.e., conductivity) is fitted by a double exponential function that takes into account two activation energies E₁ and E₂ (E₁>E₂), as shown in the equation 1 below. The fitting parameters E₁ and E₂ respectively correspond to a thermal activation energy from the singly occupied donor state to the conduction band and a thermal activation energy from the doubly occupied donor state to the conduction band. Two pre-exponential factors C₁ and C₂ in the equation 1 are also fitting parameters that respectively correspond to amplitudes of conduction caused by electrons forming a singly-occupied donor band and a doubly-occupied donor band.

$${ρ}^{- 1} = {C}_{1} exp ( - \frac{{E}_{1}}{{k}_{B} T} ) + {C}_{2} exp ( - \frac{{E}_{2}}{{k}_{B} T} ) \qquad ( Equation 1 )$$

Here, E₁ is expressed as a function of the effective donor concentration N_{d}−Nₐ, as shown in the equations 2 and 3 below. E_{d,0} included in the equation 2 is an ionization energy when the effective donor concentration is 0, and f(K) included in the equation 3 is existence probability of another donor in the vicinity of the ionization donor and is a geometric factor including a compensation ratio K. In addition, a is the overlap of the Coulomb potentials between the ionization donors.

$$\begin{matrix}{E}_{1} = {E}_{d , 0} - {α ( {N}_{d} - {N}_{a} )}^{\frac{1}{3}} & ( Equation 2 ) \\ α = f ( K ) \frac{{e}^{2}}{4 π {ϵ}_{0} ϵ} & ( Equation 3 )\end{matrix}$$

As shown in FIG. 10, the electrical resistivities p of the samples #8 and #9 in Group C have temperature dependency and exhibit the same behavior as non-degenerate semiconductors. Therefore, the fitting analysis for the samples in Group A can also be applied to the samples in Group C.

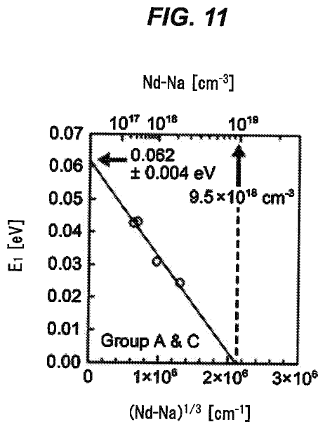

FIG. 11 is a graph showing a relationship between the energy E₁ and the effective donor concentration N_{d}−Nₐ for the samples #1, #2, #8 and #9 in the groups A and C. The approximate straight line shown in FIG. 11 is obtained by linear approximation of distribution of the plotted points for the samples #1, #2, #8 and #9, and based on the fitting error in the linear approximation, a of 2.9×10⁻⁵ meVcm was experimentally obtained. A value of this α is close to 3.6×10⁻⁵ meVcm which is a theoretical value calculated from the equation 3 based on f=Γ(2/3)(4π/3)1/3 (see, e.g., Non-Patent Literature “W. Gotz, R. S. Kern, C. H. Chen, H. Liu, D. A. Steigerwald, and R. M. Fletcher, Mater. Sci. Eng. B 59, 211 (1999).”), and demonstrates the validity of the analysis in Example 2. In addition, E_{d,0} of 62 meV was obtained as a value of E₁ at a point on the approximate straight line shown in FIG. 11 at which N_{d}−Nₐ=0.

In addition, the effective donor concentration N_{d}−Nₐ at the point on the approximate straight line shown in FIG. 11 at which E₁ is 0 was 9.5×10¹⁸ cm⁻³. Since E₁=0 means that the Fermi level and the conduction band are degenerated, it was found that the lower limit of the effective donor concentration N_{d}−Nₐ at which degeneracy of the Fermi level and the conduction band occurs in Al_{0.62}Ga_{0.38}N is 9.5×10¹⁸ cm⁻³.

### Example 3

Described next is the derivation method to derive that the lower limit of the effective donor concentration N_{d}−Nₐ at which degeneracy occurs in AlGaN with the Al composition x of 0.5 (Al_{0.5}Ga_{0.5}N) is 7.6×10¹⁸ cm⁻³, and the lower limit of the effective donor concentration N_{d}−Nₐ at which degeneracy occurs in AlGaN with the Al composition x of 1 (AlN) is 1.6×10¹⁹ cm⁻³, which is mentioned above in the embodiment of the invention.

In this derivation method, firstly, under the assumption that E_{d,0} and a in AlGaN have a linear relationship with the Al composition x, values of E_{d,0} and values of a for AlGaN with the Al compositions x of 0.5 and 1 are calculated based on the value of E_{d,0} (62 meV) and the value of a (2.9×10⁻⁵ meVcm) for the AlGaN with the Al composition x of 0.62 obtained in Example 2 described above and the value of E_{d,0} (27.0 meV) and the value of a (2.3×10⁻⁵ meVcm) for AlGaN with the Al composition x of 0 (GaN) disclosed in Non-Patent Literature “A. Wolos et al., “Properties of metal-insulator transition and electron spin relaxation in GaN:Si”, PHYSICAL REVIEW B 83, 165206 (2011)”.

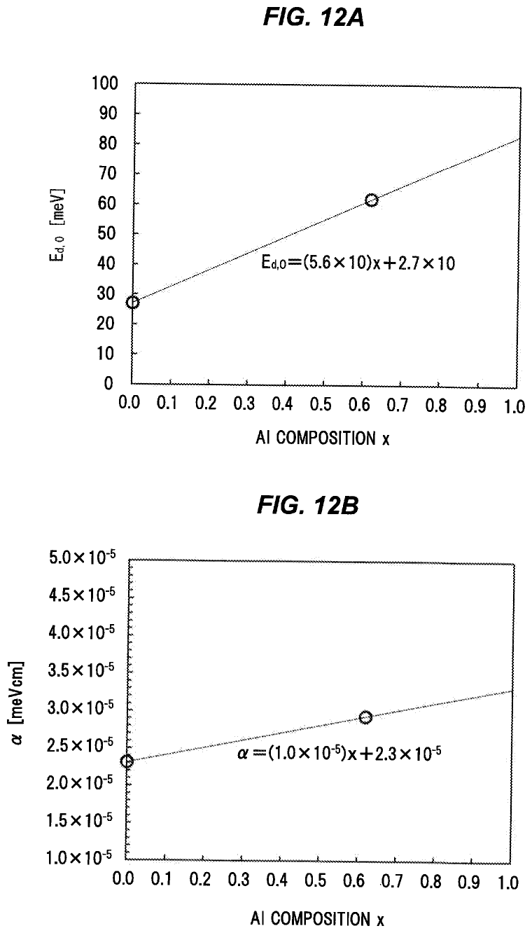

FIG. 12A is a graph showing plotted points of values of E_{d,0} for AlGaN with the Al composition x of 0 and AlGaN with the Al composition x of 0.62, and also showing a straight line passing through these two points. When the values of E_{d,0} at points on the straight line shown in FIG. 12A at which the Al composition x is 0.5 and 1 are E_{d,0} of AlGaN with the Al compositions x of 0.5 and 1, the values of E_{d,0} for AlGaN with the Al compositions x of 0.5 and 1 are respectively 55.2 meV and 83.3 meV.

FIG. 12B is a graph showing plotted points of values of a for the AlGaN with the Al composition x of 0 and the AlGaN with the Al composition x of 0.62, and also showing a straight line passing through these two points. When the values of a at points on the straight line shown in FIG. 12B at which the Al composition x is 0.5 and 1 are a of AlGaN with the Al compositions x of 0.5 and 1, the values of a for AlGaN with the Al compositions x of 0.5 and 1 are respectively 2.8×10⁻⁵ meVcm and 3.3×10⁻⁵ meVcm.

Then, using the values of E_{d,0} and the values of a for AlGaN with the Al compositions x of 0.5 and 1, N_{d}−Nₐ when E₁=0, i.e., the lower limits of the effective donor concentration N_{d}−Nₐ at which degeneracy occurs were calculated to be 7.6×10¹⁸ cm⁻³ and 1.6×10¹⁹ cm⁻³ from the equation 2.

Although the embodiment and Examples of the invention have been described, the invention is not limited to the embodiment and Examples, and the various kinds of modifications can be implemented without departing from the gist of the invention. In addition, the constituent elements in the embodiment can be arbitrarily combined without departing from the gist of the invention.

In addition, the embodiment and Examples described above do not limit the invention according to claims. Further, please note that not all combinations of the features described in the embodiment and Examples are necessary to solve the problem of the invention.

1. A light-emitting element, comprising:
an n-type contact layer which comprises AlGaN and in which a Fermi level and a conduction band are in degeneracy; and
a light-emitting layer comprising AlGaN and being stacked on the n-type contact layer,
wherein an Al composition x of the n-type contact layer is not less than 0.1 greater than an Al composition x of the light-emitting layer, and
wherein the n-type contact layer has an effective donor concentration that is a concentration to cause the degeneracy and that is not more than 4.0×10¹⁹ cm⁻³.

2. The light-emitting element according to claim 1, wherein the effective donor concentration in the n-type contact layer is (−3.0×10¹⁸) x³+(9.3×10¹⁸) x²+(8.1×10¹⁸) x+1.6×10¹⁸ cm⁻³ (where x is the Al composition x of the n-type contact layer).

3. The light-emitting element according to claim 1, wherein the Al composition x of the n-type contact layer is not less than 0.5.

4. The light-emitting element according to claim 1, wherein the Al composition x of the n-type contact layer is not more than 0.7.

5. The light-emitting element according to claim 1, wherein electrical resistivity of the n-type contact layer is not more than 5×10⁻² Ω·cm.

6. A method for manufacturing a light-emitting element, comprising:
by a vapor-phase growth method, forming an n-type contact layer which comprises AlGaN and in which a Fermi level and a conduction band are in degeneracy; and
forming a light-emitting layer comprising AlGaN on the n-type contact layer,
wherein an Al composition x of the n-type contact layer is not less than 0.1 greater than an Al composition x of the light-emitting layer,
wherein the n-type contact layer has an effective donor concentration that is a concentration to cause the degeneracy and that is not more than 4.0×10¹⁹ cm⁻³, and
wherein a V/III ratio of a source gas of the n-type contact layer in the forming the n-type contact layer is within a range of not less than 1000 and not more than 3200.

7. The method according to claim 6, wherein a growth temperature of the n-type contact layer in the forming of the n-type contact layer is not more than 1150° C.
